(19) United States
(12) Patent Application Publication
(10) Pub. No.: US 2026/0068532 A1
(43) Pub. Date: Mar. 5, 2026

(54) CRYSTAL OSCILLATION CHIP

(71) Applicant: TXC Corporation, Taipei City (TW)

(72) Inventors: Zong-De Lin, Taipei City (TW); Yi-Chieh Tsai, Taipei City (TW)

(73) Assignee: TXC Corporation, Taipei City (TW)

(21) Appl. No.: 18/943,840

(22) Filed: Nov. 11, 2024

(30) Foreign Application Priority Data
Aug. 30, 2024 (TW) 113132821

(51) Int. Cl. H10N 30/88; H10N 30/20; H10N 30/87

(52) U.S. Cl. CPC H10N 30/88; H10N 30/202; H10N 30/87

(57) ABSTRACT

A crystal oscillation chip including a casing and a crystal oscillation piece is provided. The crystal oscillation piece is disposed in the casing. The crystal oscillation piece includes a flat substrate, two electrodes and two conductive silver glues, the two electrodes are respectively disposed on two opposite main surfaces of the flat substrate. The flat substrate includes at least one notch. The notch is disposed at a side surface of the flat substrate and is recessed along a direction vertical from the side surface and toward an interior of the flat substrate. A height of the notch is the same as a thickness of the flat substrate, and two conductive silver glues connect the flat substrate and the casing.

### CROSS-REFERENCE TO RELATED APPLICATION

This application claims the priority benefit of Taiwan application serial no. 113132821 filed on Aug. 30, 2024. The entirety of the above-mentioned patent application is hereby incorporated by reference herein and made a part of this specification.

### BACKGROUND

### Technical Field

The disclosure relates to a crystal oscillation chip.

### Description of Related Art

Due to physical limitations, the main wave (e.g., the thickness shear vibration mode) of the modern crystal oscillation chip including crystal oscillation pieces is often accompanied by secondary waves such as bending vibration and face shear vibration at nearby frequencies. Secondary waves with frequencies too close to the main wave may easily couple with it, leading to poor vibration characteristics of the chip, resulting in unwanted modes. As the modern chip pursues high frequency and miniaturization, to avoid the aforementioned problems, the error range for the chip size design becomes smaller, resulting in lower production yield and hindering chip development.

### SUMMARY

The disclosure provides a crystal oscillation chip that may improve the vibration characteristics.

The crystal oscillation chip of the disclosure includes a casing and a crystal oscillation piece. The crystal oscillation piece is disposed in the casing. The crystal oscillation piece includes a flat base plate, two electrodes, and two conductive silver adhesives, the two electrodes are respectively disposed on two opposite main surfaces of the flat base plate. The flat base plate has at least one notch, the at least one notch is disposed at a side surface of the flat base plate, and depresses along a direction vertical to the side surface towards an interior of the flat base plate. A height of the at least one notch is the same as a thickness of the flat base plate, the two conductive silver adhesives connect the flat base plate and the casing.

Based on the above, the crystal oscillation piece of the crystal oscillation chip of the disclosure includes a flat base plate, the electrodes disposed on the flat base plate, and a notch depressed from the side surface of the flat base plate. The crystal oscillation piece improves the vibration characteristics of the crystal oscillation chip through the notch, thereby elevating the production yield of the crystal oscillation chip and being beneficial to development.

### BRIEF DESCRIPTION OF THE DRAWINGS

FIG. 1A is an exploded view of a crystal oscillation chip according to an embodiment of the disclosure.

FIG. 1B is a schematic view from another angle of the crystal oscillation piece of FIG. 1A.

FIG. 2 is a top view of the crystal oscillation piece of FIG. 1A.

FIG. 3 is a top view of a crystal oscillation piece according to another embodiment of the disclosure.

FIG. 4 is a top view of a crystal oscillation piece according to another embodiment of the disclosure.

FIG. 5 is a top view of a crystal oscillation piece according to another embodiment of the disclosure.

FIG. 6A is a top view of a crystal oscillation piece according to another embodiment of the disclosure.

FIG. 6B is a top view of a crystal oscillation piece according to another embodiment of the disclosure.

FIG. 6C is a top view of a crystal oscillation piece according to another embodiment of the disclosure.

FIG. 7 is a top view of a crystal oscillation piece according to another embodiment of the disclosure.

FIG. 8 is a top view of a crystal oscillation piece according to another embodiment of the disclosure.

### DETAILED DESCRIPTION OF DISCLOSED EMBODIMENTS

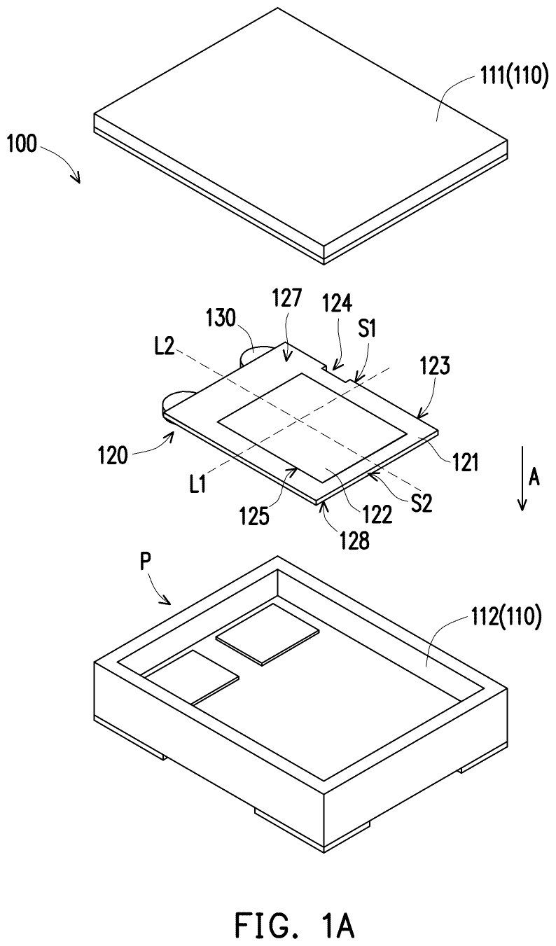

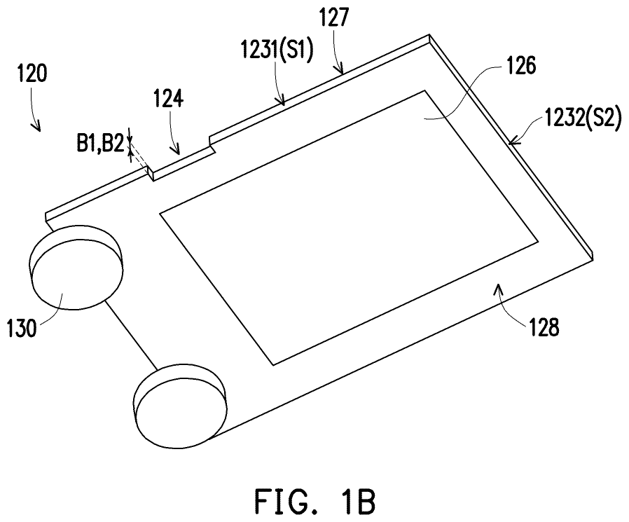

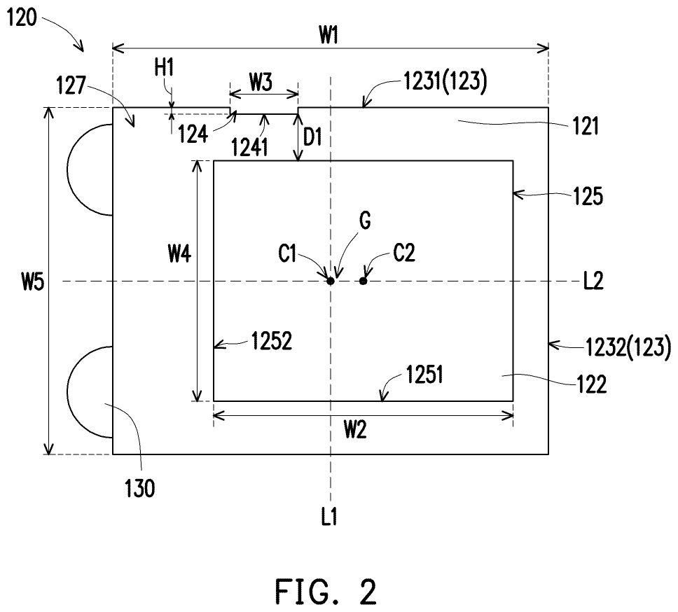

FIG. 1A is an exploded view of a crystal oscillation chip according to an embodiment of the disclosure. FIG. 1B is a schematic view from another angle of the crystal oscillation piece of FIG. 1A. FIG. 2 is a top view of the crystal oscillation piece in FIG. 1A. Please refer to FIG. 1A to FIG. 2 simultaneously, the crystal oscillation chip 100 includes a casing 110 and a crystal oscillation piece 120. The crystal oscillation piece 120 is disposed in the casing 110, and includes a flat base plate 121, two electrodes 122, 126, and two conductive silver adhesives 130. The two electrodes 122, 126 are disposed on the opposite two main surfaces of the flat base plate 121, namely an upper surface 127 and a lower surface 128. The flat base plate 121 has at least one notch 124. The notch 124 is disposed at a side surface 123 of the flat base plate 121, and is depressed along a direction vertical to the side surface 123 towards an interior of the flat base plate 121. A height B1 of the notch 124 is the same as a thickness B2 of the flat base plate 121. The two conductive silver adhesives 130 connect the flat base plate 121 and the casing 110.

The notch 124 may be formed through an etching process, but not limited thereto. By disposing the notch 124 on the side surface 123 of the flat base plate 121, the crystal oscillation chip 100 could effectively suppress the secondary wave (for example, bending vibration, face shear vibration) of the crystal oscillation chip 100 without affecting the main wave (for example, thickness shear vibration mode) of the crystal oscillation chip 100. Thereby, the crystal oscillation chip 100 allows for larger manufacturing errors, thus elevating the production yield of the crystal oscillation chip 100, and could be developed more efficiently.

As shown in FIG. 1A, the casing 110 includes a first casing 111 and a second casing 112. The first casing 111 is connected to the second casing 112 to form a storage space P, and the crystal oscillation piece 120 is located within the storage space P. The crystal oscillation chip 100 of this embodiment is in a rectangle shape, but not limited thereto.

As shown in FIG. 1B and FIG. 2, the side surface 123 of the flat base plate 121 connects between the two main surfaces (the upper surface 127 and the lower surface 128), and includes two first side surfaces 1231 and two second side surfaces 1232 connected to each other. The flat base plate 121 of this embodiment is a rectangle, but not limited thereto. The first side surfaces 1231 are located between the two second side surfaces 1232. A length W1 of the first side surface 1231 is greater than a length W5 of the second side surface 1232. The first side surface 1231 is a long side S1, and the second side surface 1232 is a short side S2.

The shapes of the two electrodes 122, 126 may be different, but are not limited to this. The electrode 122 is a first electrode, and the electrode 126 is a second electrode. The electrode 122 includes a side 125, and the side 125 corresponds to the side surface 123 of the flat base plate 121. The side 125 includes two first sides 1251 and two second sides 1252, and the two first sides 1251 connected between the two second sides 1252. The first side 1251 corresponds to the first side surface 1231 (the long side S1), and the second side 1252 corresponds to the second side surface 1232 (the short side S2). A length W2 of the first side 1251 of the electrode 122 is greater than a length W4 of the second side 1252. The electrode 122 is in a square shape, but not limited thereto. Each side (the first side 1251 and the second side 1252) of the square electrode 122 is separated by a distance from the corresponding side surface 123 (the first side surface 1231 and the second side surface 1232) of the flat base plate 121. A length W3 of the notch 124 is smaller than the lengths W2, W4 of each side of the square electrode 122.

The flat base plate 121 further includes a chip center C1 and a center axis. The chip center C1 is the geometric center of the flat base plate 121. The center axis passes through the chip center C1 and is perpendicular to the side surface 123 of the flat base plate 121. The center axis includes a first center axis L1 and a second center axis L2. The first center axis L1 is different from the second center axis L2, specifically, the first center axis L1 is perpendicular to the second center axis L2, and intersects with the second center axis L2 at the chip center C1. The first center axis L1 is perpendicular to the two first side surfaces 1231, and the second center axis L2 is perpendicular to the two second side surfaces 1232. In this embodiment, there is a gap G between the chip center C1 of the flat base plate 121 and a geometric center C2 of the electrode 122. That is, the electrode 122 is offset on the flat base plate 121. The geometric center C2 of the electrode 122 is located on the second center axis L2, but not limited thereto.

As shown in FIG. 1A and FIG. 2, the number of notches 124 in this embodiment is one, but not limited thereto. The notch 124 is depressed from the first side surface 1231 of the flat base plate 121 towards the electrode 122, and corresponds to the first side 1251 of the electrode 122 and the long side S1 (the first side surface 1231) of the flat base plate 121. A ratio of a depth H1 of the notch 124 depressed towards the electrode 122 to the length of the corresponding side surface 123 (here, the length W1 of the first side surface 1231) is less than or equal to 0.4. A Length W3 of the notch 124 is less than or equal to the length of the corresponding side 125 (here, the length W2 of the first side 1251). There is a distance D1 between a bottom edge 1241 of the notch 124 and the corresponding side 125 (the first side 1251) of the electrode 122. The orthographic projection of the notch 124 to the electrode 122 is located at the corresponding side 125 (the first side 1251), but not limited thereto. The notch 124 penetrates through the flat base plate 121 in a thickness direction A. The thickness direction A is perpendicular to the extending direction of the center axis (the first center axis L1 and the second center axis L2).

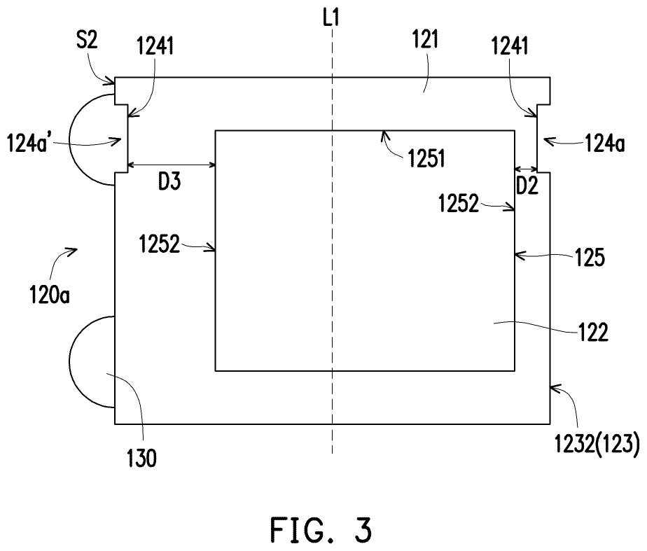

FIG. 3 is a top view of a crystal oscillation piece according to another embodiment of the disclosure. Please refer to FIG. 2 and FIG. 3 at the same time, the crystal oscillation piece 120a of this embodiment is similar to the previous embodiment. The difference between the two is that the notch of the crystal oscillation piece 120a of this embodiment includes a pair of first notches 124a, 124a′. The pair of first notches 124a, 124a′ is symmetrically disposed at the two opposite side surfaces 123 (the second side surfaces 1232) of the flat base plate 121, with the first center axis L1 of the flat base plate 121 as a symmetry axis, and corresponds to the short side S2 of the flat base plate 121. The orthographic projection of the first notches 124a, 124a′ to the electrode 122 is partially located at the corresponding second sides 1252 (the sides 125). The distance D2 between the first notch 124a and the corresponding second side 1252 is less than or equal to the distance D3 between the first notch 124a′ and the corresponding second side 1252. The position where the conductive silver adhesive 130 is disposed corresponds to the first notch 124a′, but not limited thereto. The crystal oscillation piece 120a of this embodiment has the similar effect as the previous embodiment, and is not repeated herein.

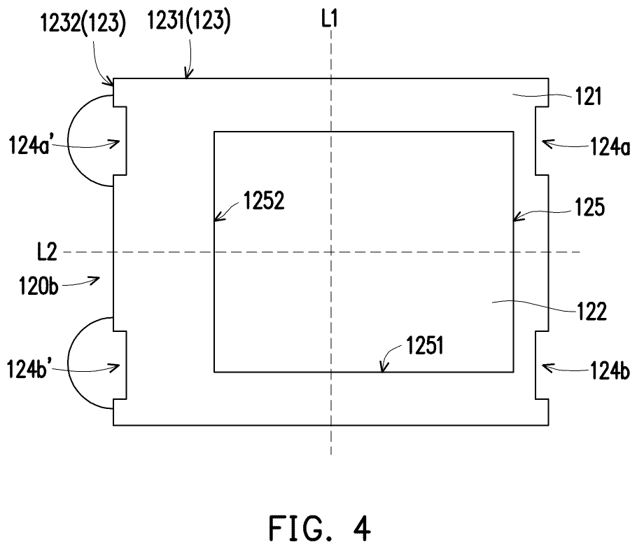

FIG. 4 is a top view of a crystal oscillation piece according to another embodiment of the disclosure. Please refer to FIG. 3 and FIG. 4 at the same time, the crystal oscillation piece 120b of this embodiment is similar to the previous embodiment. The difference between the two is that the crystal oscillation piece 120b of this embodiment further includes a pair of second notches 124b, 124b′. The pair of second notches 124b, 124b′ is correspondingly disposed at the two side surfaces 123 (the second side surfaces 1232) of the flat base plate 121. The second notches 124b, 124b′ and the first notches 124a, 124a′ are symmetrically disposed at the two sides of the center axis (the second center axis L2). Here, the first notches 124a, 124a′ and the second notches 124b, 124b′ may be viewed as symmetrically disposed at the two second side surfaces 1232 of the flat base plate 121, with the first center axis L1 and the second center axis L2 as the symmetry axes respectively, and corresponding to the two second sides 1252 of the electrode 122. One conductive silver adhesive 130 corresponds to the first notch 124a′, while another conductive silver adhesive 130 corresponds to the second notch 124b′, but not limited thereto. The crystal oscillation piece 120b of this embodiment has the similar effect as the previous embodiment, and is not repeated herein.

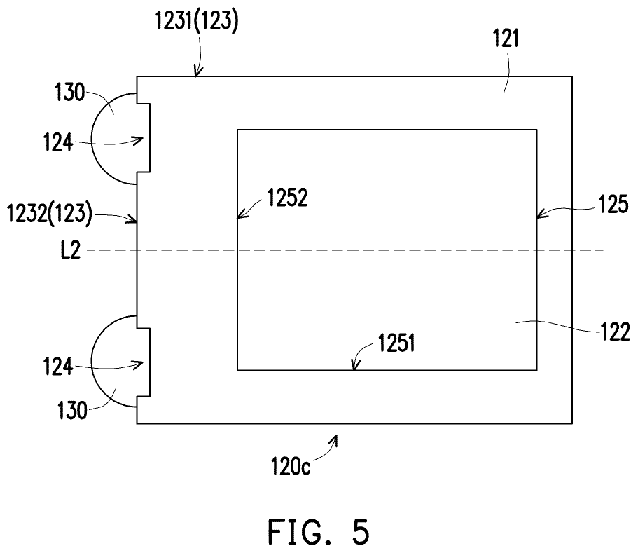

FIG. 5 is a top view of a crystal oscillation piece according to another embodiment of the disclosure. Please refer to FIG. 3 and FIG. 5 at the same time, the crystal oscillation piece 120c of this embodiment is similar to the previous embodiment. The difference between the two is that the two notches 124 of the crystal oscillation piece 120c of this embodiment are symmetrically disposed at one side surface 123 (the second side surface 1232) of the flat base plate 121, with the second center axis L2 of the flat base plate 121 as the symmetry axis. The two conductive silver adhesives 130 correspond to the two notches 124, but not limited thereto. The crystal oscillation piece 120c of this embodiment has the same effect as the previous embodiment, and is not repeated herein.

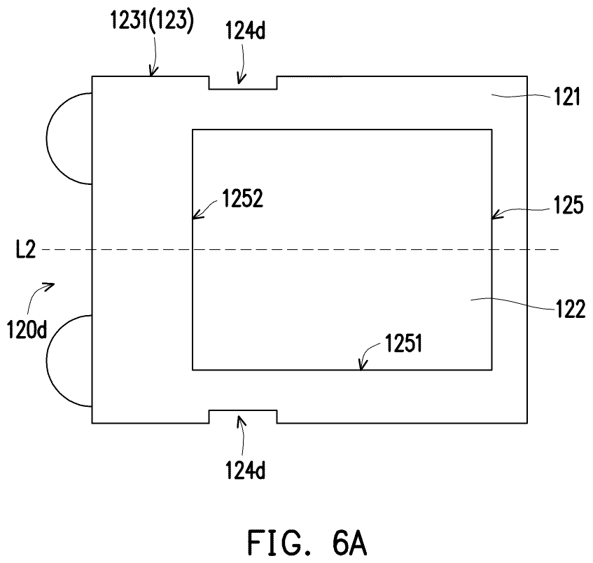

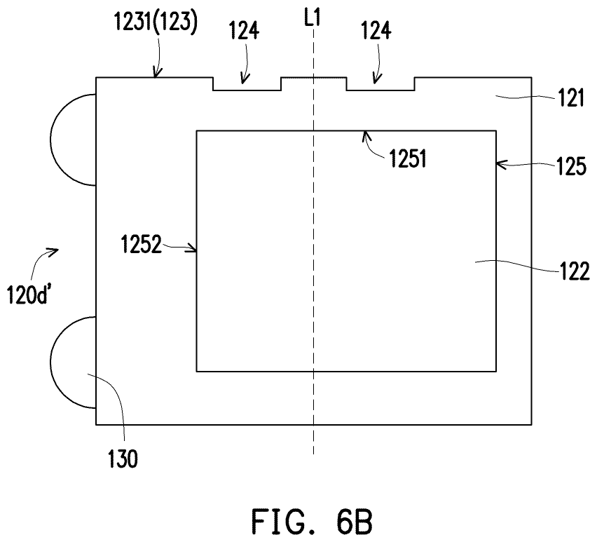

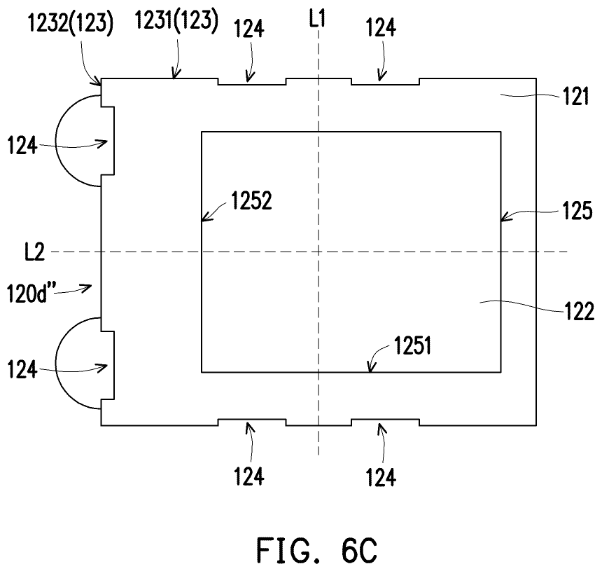

FIG. 6A is a top view of a crystal oscillation piece according to another embodiment of the disclosure. Please refer to FIG. 3 and FIG. 6A at the same time, the crystal oscillation piece 120d of this embodiment is similar to the previous embodiment. The difference between the two is that the pair of first notches 124d of the crystal oscillation piece 120d of this embodiment are symmetrically disposed at the two side surfaces 123 (the first side surfaces 1231) of the flat base plate 121, with the second center axis L2 of the flat base plate 121 as the symmetry axis, and corresponding to the two first sides 1251 of the electrode 122. The crystal oscillation piece 120d of this embodiment has the same effect as the previous embodiment, and is not repeated herein.

In an embodiment not shown, the crystal oscillation piece 120d may include a pair of second notches. The second notches may be symmetrically disposed at the two first side surfaces 1231 of the flat base plate 121, with the second center axis L2 as the symmetry axis, and located next to the first notches 124d.

FIG. 6B is a top view of a crystal oscillation piece according to another embodiment of the disclosure. Please refer to FIG. 3 and FIG. 6B at the same time, the crystal oscillation piece 120d′ of this embodiment is similar to the previous embodiment. The difference between the two is that the notches 124 of the crystal oscillation piece 120d′ of this embodiment are symmetrically disposed at one side surface 123 (the first side surface 1231) of the flat base plate 121, with the first center axis L1 as the symmetry axis. The orthographic projections of the two notches 124 to the electrode 122 are located at the corresponding side 125 (the first side 1251). The crystal oscillation piece 120d′ of this embodiment has the same effect as the previous embodiment, and is not repeated herein.

FIG. 6C is a top view of a crystal oscillation piece according to another embodiment of the disclosure. Please refer to FIG. 3 and FIG. 6C at the same time, the crystal oscillation piece 120d″ of this embodiment is similar to the previous embodiment. The difference between the two is that the crystal oscillation piece 120d″ of this embodiment includes the six notches 124. The six notches 124 are symmetrically disposed at the three side surfaces 123 (the two first side surfaces 1231 and the one second side surface 1232) of the flat base plate 121, with the first center axis L1 and the second center axis L2 of the flat base plate 121 as the symmetry axes. The crystal oscillation piece 120d″ of this embodiment has the same effect as the previous embodiment, and is not repeated herein.

When producing the modern crystal oscillation chips without the notches, the allowable error value for the first side surface of the flat base plate is plus or minus 2 microns, and the allowable error value for the second side surface is plus or minus 2 microns. Whenever the sixteen modern crystal oscillation chips are produced, only the six modern crystal oscillation chips effectively eliminate the secondary wave and make the equivalent series resistance (ESR) less than 30 ohms. In the embodiment, by disposing the notches 124, when producing the crystal oscillation piece 120d″, the allowable error value for the first side surface 1231 of the flat base plate 121 may be plus or minus 4 microns, and the allowable error value for the second side surface 1232 may be plus or minus 4 microns. All of the crystal oscillation chips with the crystal oscillation piece 120d″ effectively eliminate the secondary wave and make the equivalent series resistance less than 30 ohms.

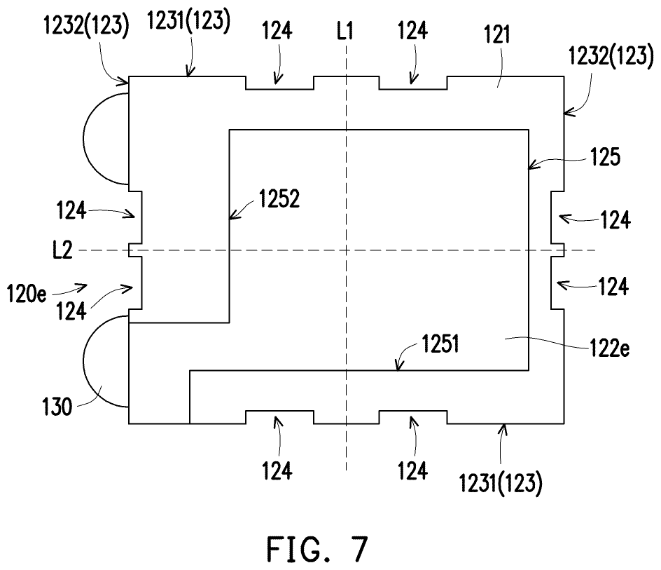

FIG. 7 is a top view of a crystal oscillation piece according to another embodiment of the disclosure. Please refer to FIG. 3 and FIG. 7 at the same time, the crystal oscillation piece 120e of this embodiment is similar to the previous embodiment. The difference between the two is that the crystal oscillation piece 120e of this embodiment includes the eight notches 124. The eight notches 124 are symmetrically disposed at the four side surfaces 123 (the two first side surfaces 1231 and the two second side surfaces 1232) of the flat base plate 121, with the first center axis L1 and the second center axis L2 of the flat base plate 121 as the symmetry axes. The electrode 122e has a polygon shape. The electrode 122e extends to the first side surfaces 1231 and the second side surfaces 1232 of the flat base plate 121. The notches 124 are staggered with the conductive silver adhesives 130. The crystal oscillation piece 120e of this embodiment has the same effect as the previous embodiment, and is not repeated herein.

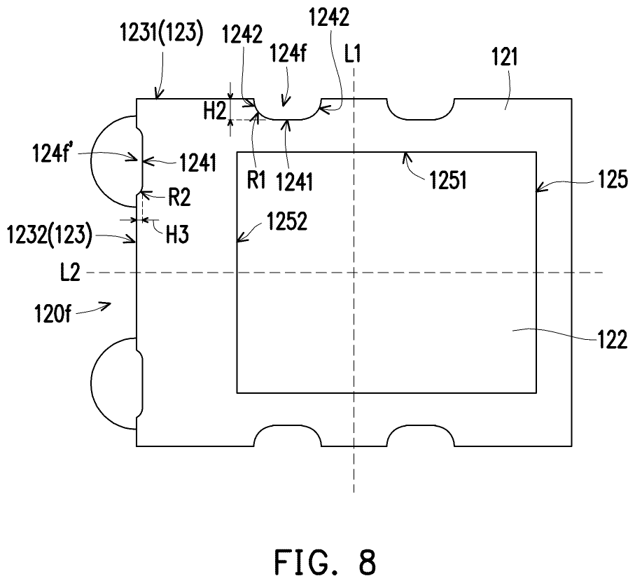

FIG. 8 is a top view of a crystal oscillation piece according to another embodiment of the disclosure. Please refer to FIG. 6C and FIG. 8 at the same time, the crystal oscillation piece 120f of this embodiment is similar to the previous embodiment. The difference between the two is that the notch 124f, 124f′ of the crystal oscillation piece 120f of this embodiment include a rounded corner R1, R2. The rounded corner R1, R2 is disposed at a corner of the notch 124f, 124f′, which may effectively reduce the stress concentration phenomenon at the corner, to elevate the structural strength of the crystal oscillation piece 120f.

Taking the notch 124f as an embodiment, the notch 124f includes two opposite sides 1242 and a bottom side 1241, and two ends of the bottom side 1241 (i.e., at the corners of the notch 124f) are connected to the two sides 1242 respectively. The two sides 1242 of the notch 124f are connected to the bottom side 1241 with the rounded corners R1, thus including the two rounded corners R1. In an embodiment not shown, only one side 1242 may be connected to the bottom side 1241 with the rounded corner R1, and the notch may include only one rounded corner R1.

The four notches 124f located at the first side surface 1231 are symmetrically disposed with the first center axis L1 and the second center axis L2 as the symmetry axes. The two notches 124f′ located on the second side surface 1232 are symmetrically disposed with the second center axis L2 as the symmetry axes. The R values of the rounded corners R1, R2 of the notches 124f, 124f′ with different center axes as the symmetry axes may be different, and the depths H2, H3 of the notches 124f, 124f′ may be different. Specifically, the R value of the rounded corner R1 of the notch 124f is greater than the R value of the rounded corner R2 of the notch 124f′, and the depth H2 of the notch 124f is greater than the depth H3 of the notch 124f′. The crystal oscillation piece 120f of this embodiment has the same effect as the previous embodiment, and is not repeated herein.

The quantity and disposed way of the notches 124 of the crystal oscillation pieces 120, 120a, 120b, 120c, 120d, 120d′, 120d′, 120f may be changed according to the structure and purpose of the crystal oscillation piece, and are not limited to the previous embodiments.

In summary, the crystal oscillation piece of the crystal oscillation chip of the disclosure includes a flat base plate, the electrodes disposed on the flat base plate, and a notch depressed from the side surface of the flat base plate. The crystal oscillation piece improves the vibration characteristics of the crystal oscillation chip through the notch, thereby elevating the production yield of the crystal oscillation chip and being beneficial to development.

What is claimed is:

1. A crystal oscillation chip, comprising:
a casing; and
a crystal oscillation piece, disposed in the casing, the crystal oscillation piece comprises a flat base plate, two electrodes and two conductive silver adhesives, the two electrodes are respectively disposed on two opposite main surfaces of the flat base plate, the flat base plate has at least one notch, the at least one notch is disposed at a side surface of the flat base plate, and depresses along a direction vertical to the side surface towards an interior of the flat base plate, a height of the at least one notch is the same as a thickness of the flat base plate, the two conductive silver adhesives connect the flat base plate and the casing.

2. The crystal oscillation chip according to claim 1, wherein a ratio of a depth of each of the at least one notch to a length of the side surface is less than or equal to 0.4.

3. The crystal oscillation chip according to claim 1, wherein the at least one notch comprises a pair of first notches, the pair of first notches are correspondingly disposed at two opposite side surfaces of the flat base plate.

4. The crystal oscillation chip according to claim 3, wherein the at least one notch further comprises a pair of second notches, correspondingly disposed at the two side surfaces of the flat base plate, the pair of second notches and the pair of first notches are symmetrically disposed at two sides of a center line passing through a chip center of the crystal oscillation piece and vertical to the two side surfaces.

5. The crystal oscillation chip according to claim 1, wherein the side surface comprises two first side surfaces and two second side surfaces connected to each other, each of the two first side surfaces is located between the two second side surfaces, the at least one Notch comprises a plurality of notches, the plurality of notches are symmetrically disposed on at least one of the two first side surfaces or the two second side surfaces with a first center axis of the flat base plate as a symmetry axis.

6. The crystal oscillation chip according to claim 1, wherein the side surface comprises two first side surfaces and two second side surfaces connected to each other, each of the two first side surfaces is located between the two second side surfaces, the at least one notch comprises a plurality of notches, the plurality of notches are symmetrically disposed on at least one of the two second side surfaces or the two second side surfaces with a second center axis of the flat base plate as a symmetry axis.

7. The crystal oscillation chip according to claim 1, wherein there is a gap between a chip center of the flat base plate and a geometric center of one of the two electrodes.

8. The crystal oscillation chip according to claim 1, wherein the at least one notch comprises two opposite sides, and a bottom side connecting the two sides at both ends.

9. The crystal oscillation chip according to claim 8, wherein at least one of the two sides is connected to the bottom side with a rounded corner.

10. The crystal oscillation chip according to claim 1, wherein at least one of the two electrodes has a square shape, each side of the square shape is separated from the corresponding side surface of the flat base plate by a distance.

11. The crystal oscillation chip according to claim 10, wherein a length of the at least one notch is less than a length of the side of the square shape.

12. The crystal oscillation chip according to claim 1, wherein each of the two electrodes comprises a side, the side corresponds to the side surface of the flat base plate, an orthographic projection of the at least one notch to each of the two electrodes is at least partially located on the side.

13. The crystal oscillation chip according to claim 1, wherein the casing comprises a first casing and a second casing, the first casing is connected to the second casing to form a storage space, the crystal oscillation piece is located within the storage space.

14. The crystal oscillation chip according to claim 1, wherein the at least one notch penetrates through the flat base plate in a thickness direction.

15. The crystal oscillation chip according to claim 1, wherein a first center axis and a second center axis of the flat base plate intersect at a chip center of the flat base plate, a thickness direction is perpendicular to an extending direction of the first center axis, and perpendicular to an extending direction of the second center axis.

16. The crystal oscillation chip according to claim 1, wherein the at least one notch corresponds to at least one long side of the flat base plate.

17. The crystal oscillation chip according to claim 1, wherein the at least one notch corresponds to at least one short side of the flat base plate.
